(19) United States
(12) Patent Application Publication
(10) Pub. No.: US 2008/0309406 A1
(43) Pub. Date: Dec. 18, 2008

(54) Full-Bridge Class-D Power Amplifier

(75) Inventor: Rudi Jonkman, Eindhoven (NL)

Correspondence Address: THORNE & HALAJIAN;APPLIED TECHNOLOGY CENTER, 111 WEST MAIN STREET, BAY SHORE, NY, 11706, US

(73) Assignee: BOBINADOS DE TRANSFORMADORES S.L., Zaragoza (ES)

(21) Appl. No.: 12/095,472

(22) PCT Filed: Nov. 28, 2006
(86) PCT No.: PCT/IB2006/054480

§ 371 Date: May 30, 2008

(30) Foreign Application Priority Data
Dec. 2, 2005 (EP) 05111605.1

(51) Int. Cl. H03F 3/217

(52) U.S. Cl. 330/251

(57) ABSTRACT

The present invention relates to a full bridge class-D amplifier where one of the output terminals (27) is grounded, and which is arranged to be supplied by a floating power supply (1). Each amplifier switching leg (7, 15) is connected to the corresponding load terminal (25, 27) via a low-pass filter (29, 31), at least one of which comprises a capacitor (C1, C2, C3 or C4), connected between the load terminal and the positive or negative output terminal (3, 5) of the floating power supply.

### FIELD OF THE INVENTION

The present invention relates to a full-bridge class-D power amplifier comprising a first switching leg, having a first and a second controllable switch, which are interconnected in a first connection point and connected in series to the positive and negative terminals of a power supply, a second switching leg, having a third and a fourth controllable switch, which are interconnected in a second connection point and connected in series to the positive and negative terminals of the power supply, a first low pass filter being connected between the first connection point and a first load terminal, the second connection point being connected to a second load terminal and the first or the second load terminal being connected to earth by means of an earth connection.

### BACKGROUND OF THE INVENTION

Such an amplifier is disclosed in U.S. Pat. No. 6,259,317, B1. An advantage with such an amplifier is, since an output terminal is grounded, that the output voltage does not have a common mode voltage component. This makes it possible to use a less complicated feedback arrangement to control the amplifier.

In such a full-bridge amplifier, the positive and negative terminals of the power supply are alternately connected to ground with the switching frequency. This means that no capacitance should be allowed from any load connection to the power supply, not even a parasitic capacitance. In practice however, there is always a parasitic capacitance present. This transmits a switching noise to the load. The signal to noise ratio may thus be low. This is of course undesired e.g. in audio applications where the thus induced interference may be audible.

### SUMMARY OF THE INVENTION

An object of the present invention is therefore to provide a class-D amplifier with improved signal to noise ratio.

This object is achieved by means of a full bridge class-D amplifier as defined in claim 1.

More specifically, in an amplifier of the initially mentioned kind the second connection point is then connected to the second load terminal via a second low pass filter, and at least one of the first and second low pass filters comprises a capacitor connected to the positive or negative terminal of the power supply. Such a filter arrangement provides improved noise insulation, since the power supply positive and negative terminals will be balanced around the ground level, and hence improved signal to noise ratio.

Preferably each of the first and second low-pass filters has a capacitor connected to the positive or negative terminal of the power supply. This achieves the inventive effect even if a connected load does not have a substantial capacitive characteristic.

Even more improved properties are achieved when the first low-pass filter has a capacitor connected between the first load terminal and the positive terminal of the power supply and a capacitor connected between the first load terminal and the negative terminal of the power supply, and the second low-pass filter has a capacitor connected between the second load terminal and the positive terminal of the power supply and a capacitor connected between the second load terminal and the negative terminal of the power supply. Such filter arrangement will provide, due to its symmetry, a reconstructed and amplified audio signal by means of averaging and guarantee good balancing of the power supply.

The used switches may be MOSFET switches.

The amplifier may be arranged to be connected in a bridge tied load (BTL) arrangement with a similar auxiliary full-bridge class-D power amplifier.

These and other aspects of the invention will be apparent from and elucidated with reference to the embodiments described hereinafter.

### BRIEF DESCRIPTION OF THE DRAWINGS

FIG. 1 illustrates schematically an asymmetric full-bridge class-U amplifier according to an embodiment of the invention.

FIG. 2 illustrates the amplifier of FIG. 1 with an arrangement for providing a floating power supply.

FIG. 3 illustrates the amplifier of FIG. 1 with a control arrangement.

FIG. 4 illustrates two amplifiers of the kind shown in FIG. 1 arranged in a bridge-tied load (BTL) configuration.

### DESCRIPTION OF PREFERRED EMBODIMENTS

Full-bridge class-D amplifiers are often used in e.g. high power audio applications due to their high power efficiency. In a conventional full-bridge configuration the load is usually floating, at a common mode voltage that equals half the power supply voltage. This causes a problem when designing a feedback arrangement for the amplifier, since the differential voltage over the load must be measured with a very high common-mode rejection ratio (CMRR). This can be done by scaling down each load terminal voltage by means of a precision divider and subtracting the two resulting voltages from each other in order to obtain a differential value used for feedback purposes. The voltage dividers used must then be very well matched in order to achieve low total harmonic distortion and noise, which is of course very important in audio applications.

One way of reducing the common mode influence is to use a full-bridge amplifier with a symmetric dual supply voltage, i.e. a power source providing a positive and a negative voltage, which are symmetrically referenced to ground. However, a drawback with this type of amplifier stage is that it cannot be used in a so-called bridge-tied load (BTL) configuration, where two full-bridge class-D amplifiers are used to supply a load with high power.

An asymmetric full-bridge class-D amplifier according to an embodiment of the invention, can be used in a BTL configuration and does not have a common mode output voltage at all, as will now be described.

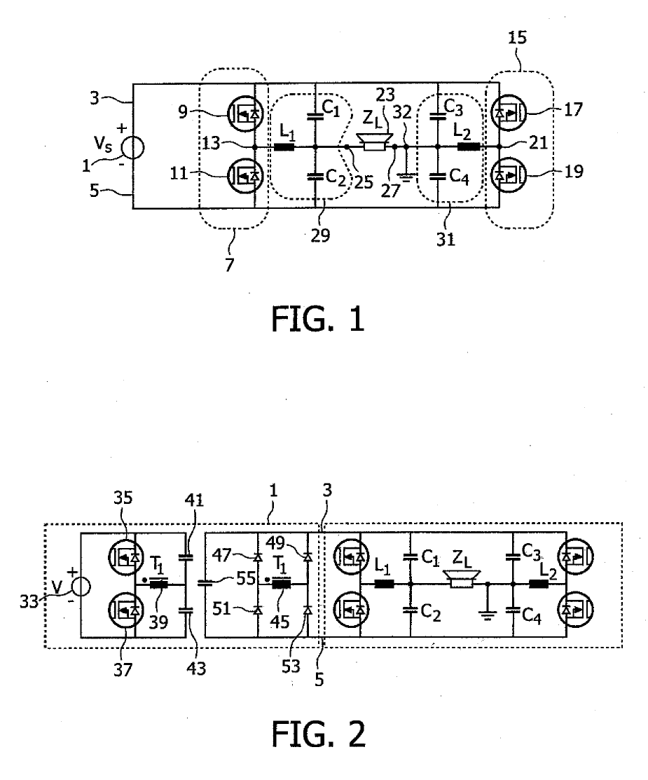

FIG. 1 illustrates schematically an asymmetric full-bridge class-D amplifier stage according to an embodiment of the invention. The stage has a floating voltage power supply 1, providing a positive potential Vₛ₊ at a positive terminal 3 and a negative potential Vₛ₋ (negative in relation to the positive potential) at a negative terminal 5. The power supply is arranged to provide a substantially constant voltage (Vₛ=Vₛ₊−Vₛ₋), but the absolute potentials are floating in relation to ground. A power supply arrangement of this kind will be described in more detail later.

The amplifier comprises a first switching leg 7, having a first 9 and a second 11 controllable switch, which may e.g. be MOSFET switches. The first switch 9 and the second switch 11 are interconnected in a first connection point 13 and are connected in series to the positive 3 and negative 5 terminals, respectively, of the power supply 1. A second switching leg 15, has a third 17 and a fourth 19 controllable switch, which are interconnected in a second connection point 21 and are connected in series to the positive and negative terminals, respectively, of the power supply 1.

As in a conventional class-D amplifier the switches of the first 7 and second 15 switching legs are switched complementary and in synchronization, such that in a first state the first connection point 13 is connected to the positive supply terminal 3 while the second connection point 21 is connected to the negative supply terminal 5. In a second state this is reversed, such that the first connection point 13 is connected to the negative supply terminal 5 while the second connection point 21 is connected to the positive supply terminal 3. Switching between the first and second state is carried out at a high switching frequency, typically a few hundred kHz.

A load 23 with an impedance Z_{L} can be connected to the class-D amplifier between a first 25 and a second 27-load terminal. The first load terminal 25 is connected to the first connection point 13 via a first low-pass filter 29, and the second load terminal 27 is connected to the second connection point 21 via a second low-pass filter 31. The low-pass filters 29, 31 are used to block the switching frequency from reaching the load 23 and are tuned accordingly.

In the illustrated embodiment the second load terminal 27 is connected to earth by means of an earth connection 32. Alternatively however, the first load terminal could be connected to earth. The amplifier is thus asymmetric. Thanks to the earth connection 32 and the floating power supply 1, the common mode voltage over the load is zero, which means that a simple but yet accurate feedback arrangement can be used as will be illustrated later.

As in many conventional non-asymmetric class-D amplifiers the first and second low-pass filters 29, 31 may comprise an inductor. In the first low-pass filter, the inductor L1 is connected between the first connection point 13 and the first load terminal 25. In the second low-pass filter, the inductor L2 is connected between the second connection point 21 and the second load terminal 27. The inductors serve to make the load voltage an averaged version of the voltage between the first and second connection points 13, 21 by only allowing the current through the inductors to rise and fall slowly.

In addition to the inductors, the low pass filters 29, 31 comprise capacitors connected between the respective load terminals and the positive and negative supply terminals 3, 5. Thus, in the first filter 29 one capacitor C1 is connected between the first load terminal 25 and the positive supply terminal 3 and another capacitor C2 is connected between the first load terminal 25 and the negative supply terminal 5. In the second filter 31 one capacitor C3 is connected between the second load terminal 27 and the positive supply terminal 3 and another capacitor C4 is connected between the second load terminal 27 and the negative supply terminal 5. The capacitors are used to improve the low-pass filter function and also to automatically balance the power supply. The four capacitors may preferably have substantially the same capacitance.

It should be noted that the illustrated embodiment is preferred, since it is very well balanced vis-à-vis the positive and negative supply voltages. However it may be possible to provide fewer capacitors and still obtain good results. For all loads, a capacitor on each side of the load, connected to the positive or negative supply terminal, should be enough for many less demanding applications. If the load has a capacitive characteristic it may even be enough with one capacitor attached at one side of the load.

In general, the described class-D amplifier output stage in FIG. 1 inherently balances the power supply around the ground reference point by means of duty ratio control of the switches, and the averaging output filter being connected to the power supply terminals.

Below one example of used components and settings is listed:

| Vₛ | 80 | V |
|---|---|---|
| Switches | FDP3652 (MOSFET) | |
| L₁ | 3.0 | μH |
| C₁ | 820 | nF |
| C₂ | 820 | nF |
| L₂ | 3.0 | μH |
| C₃ | 820 | nF |
| C₄ | 820 | nF |
| Z_{L} | 2 | Ω |
| Switching | 375 | kHz |
| frequency | | |

FIG. 2 illustrates the amplifier of FIG. 1 with an arrangement for providing a floating power supply 1 as used in the amplifier stage in FIG. 1. An insulated switched arrangement is used where an input voltage V from a power supply 33, that need not be floating, is used. In series with this power supply, two switches 35, 37 are series connected, and a transformer winding 39 is connected to the connection point between the two switches 35, 37. The switches 35, 37 are switched complementary, such that a first side of the transformer primary winding 39 is alternating connected to the positive and negative potential of the power supply 33. The second side of the transformer primary winding 39 is connected via two capacitors 41, 43 to the positive and negative power supply 33 potential, respectively, such that the primary transformer winding alternating forms an LC circuit with each of the capacitors driving the voltage at the second side of the primary transformer winding up and down corresponding to the switching of the switches 35, 37.

This creates an alternating current through the primary transformer winding 39, which generates a corresponding current in a secondary transformer winding 45 of the same transformer T1, which winding is insulated from the primary winding 39. The current may be rectified, as illustrated using a full bridge rectifier with four diodes 47, 49, 51, 53 which feeds the rectified current to a filter capacitor 55, thus generating a floating voltage at the power supply terminals 3, 5.

The described embodiment is only an example. A corresponding floating power supply can be achieved with other insulated converters, e.g. a fly back converter.

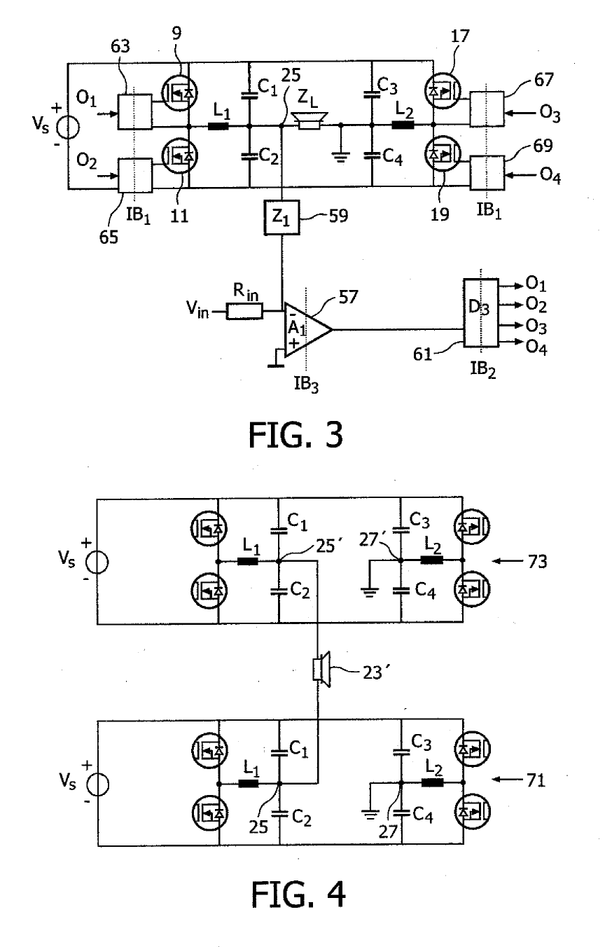

FIG. 3 illustrates the amplifier of FIG. 1 with a control arrangement. An input signal Vᵢₙ to be amplified is fed to a comparator 57 via an input impedance Rᵢₙ. In the same way the output voltage from the (not grounded) load terminal 25 is fed to the comparator via a specific feedback network 59. Expensive high-precision voltage dividers are not needed thanks to the avoided common mode voltage. The comparator generates a pulse width modulated signal that is fed to a control block 61. The control block generates control signals O₁, O₂, O₃, O₄ for each of the switches 9, 11, 17, 19 in the amplifier stage based on the pulse width modulation signal. It should be noted that the feedback signal is collected from a point after the output filter in a similar way as illustrated in WO 03/090343 A1. This feedback approach is considered particularly suitable for the above application with the floating power supply.

At one place in the control path an isolation barrier should be inserted to obtain galvanic insulation between the switches and the amplifier output. Such a barrier IB1 can be introduced in each switch's driving circuitry 63, 65, 67, and 69. Alternatively, a barrier IB2 in the control block 61 can be used. Another alternative is to have a barrier IB3 in the comparator 57. One of the barriers IB1 or IB2 is preferred, since such a barrier operates in the digital domain and can be accomplished by means of an opto-coupler or a pulse transformer with good timing characteristics.

FIG. 4 illustrates two amplifiers of the kind shown in FIG. 1 arranged in a bridge-tied load (BTL) configuration. This arrangement can be used to obtain extra high power output. Two class-D amplifiers 71, 73 of the above-described type are used. The load 23′ is connected between the not earthed load terminal 25, 25′ of each amplifier, the other load terminals 27, 27′ of each amplifier being earthed.

In summary, the invention relates to a full bridge class-D amplifier where one of the output terminals is grounded, and which is arranged to be supplied by a floating power supply. Each amplifier switching leg is connected to the corresponding load terminal via a low-pass filter, at least one of which comprises a capacitor, connected between the load terminal and the positive or negative output terminal of the floating power supply.

The invention is not restricted to the described embodiments. It can be altered in different ways within the scope of the appended claims.

1. A full-bridge class-D power amplifier comprising a first switching leg, having a first and a second controllable switch, which are interconnected in a first connection point and connected in series to the positive and negative terminals of a power supply, a second switching leg, having a third and a fourth controllable switch, which are interconnected in a second connection point and connected in series to the positive and negative terminals of the power supply, a first low pass filter being connected between the first connection point and a first load terminal, the second connection point being connected to a second load terminal and the first or the second load terminal being connected to earth by means of an earth connection, wherein
the second connection point is connected to the second load terminal via a second low pass filter, and
at least one of the first and second low pass filters comprises a capacitor connected to the positive or negative terminal of the power supply.

2. The full-bridge class-D power amplifier according to claim 1, wherein each of the first and second low-pass filters have a capacitor connected to the positive or negative terminal of the power supply.

3. The full-bridge class-D power amplifier according to claim 2, wherein the first low-pass filter has a capacitor connected between the first load terminal and the positive terminal of the power supply and a capacitor connected between the first load terminal and the negative terminal of the power supply, and wherein the second low-pass filter has a capacitor connected between the second load terminal and the positive terminal of the power supply and a capacitor connected between the second load terminal and the negative terminal of the power supply.

4. The full-bridge class-D power amplifier according to claim 1, wherein said first, second third and fourth switches are MOSFET switches.

5. The full-bridge class-D power amplifier according to claim 1, wherein the amplifier is a first one of two amplifiers connected in a bridge tied load arrangement.

6. The full-bridge class-D power amplifier according to claim 2, wherein said first, second third and fourth switches are MOSFET switches.

7. The full-bridge class-D power amplifier according to claim 3, wherein said first, second third and fourth switches are MOSFET switches.

8. The full-bridge class-D power amplifier according to claim 2, wherein the amplifier is a first one of two amplifiers connected in a bridge tied load arrangement.

9. The full-bridge class-D power amplifier according to claim 3, wherein the amplifier is a first one of two amplifiers connected in a bridge tied load arrangement.

10. The full-bridge class-D power amplifier according to claim 4, wherein the amplifier is a first one of two amplifiers connected in a bridge tied load arrangement.
